(19) United States
(12) Patent Application Publication
(10) Pub. No.: US 2008/0081407 A1
(43) Pub. Date: Apr. 3, 2008

(54) Protective coating for mark preservation

(76) Inventors: May Ling Oh, Kulim (MY); Lim Chong Sim, Glugor (MY)

Correspondence Address: INTEL/BLAKELY, 1279 OAKMEAD PARKWAY, SUNNYVALE, CA, 94085-4040, US

(21) Appl. No.: 11/529,953

(22) Filed: Sep. 29, 2006

(51) Int. Cl. H01L 21/8249

(52) U.S. Cl. 438/235

(57) ABSTRACT

A polymer coating material is disposed at a surface of a semiconductor substrate, superimposing a readable mark formed thereupon. A perimeter of the coating material is configured to correspond approximately with a perimeter of the mark, and a thickness of the coating material is configured to be relatively conformal with the surface of the substrate. The mark remains readable through the coating material throughout manufacturing, reliability testing, and normal use. A substrate so formed may constitute a portion of an assembly and/or system (e.g., computer system). Throughout manufacturing, reliability testing and normal use, a readable mark provides product identification, traceability, and other benefits.

### FIELD OF THE INVENTION

The invention relates generally to the field of semiconductor device manufacturing and packaging. In particular, the invention relates to preserving the readability of marks on semiconductor substrates.

### BACKGROUND OF THE INVENTION

IC (integrated circuit) packages are often marked for identification. The marks may be human readable, machine readable, or both. When initially marked, the marks are generally readable, however, conditions present throughout manufacturing, reliability testing, and/or normal use can degrade the readability of a mark until, occasionally, it is no longer readable. The inability to accurately and reliably read identifying or other marks on an IC package can interfere with manufacturing processes, product traceability, detection of product tampering, theft recovery, product authenticity confirmation, automated handling, inventory management, and numerous other operations throughout the lifetime of an IC device.

Reliability testing frequently includes exposing products to environmental conditions that simulate accelerated product life (e.g., use, handling), and such conditions are capable of degrading the readability of a mark. Temperature extremes, including isothermal and cyclical, high humidity, and other conditions can affect an exposed mark itself, or the materials of a substrate on which a mark is placed. Frequently a mark includes three dimensional contours relative to a plane of a surface at which the mark is formed, and the three dimensional contours provides the mark with sufficient contrast to promote readability. Under reliability test conditions, elevated portions of the contours may be smoothed and reduced in height, recessed portions may be filled in or widened, and sharp transitions between the two may be smoothed and rendered less distinct. Likewise, marks that don't include such three dimensional contours are also subject to degradation, detrimentally affecting readability.

### BRIEF DESCRIPTION OF THE DRAWINGS

FIG. 1 depicts a mark disposed at a surface of a substrate according to an embodiment of the invention.

FIG. 2 depicts a method for deterring loss of the readability of a mark according to an embodiment of the invention.

FIG. 3 depicts a coating material superimposing a mark disposed at a surface of a substrate according to an embodiment of the invention.

FIG. 4 depicts an assembly including a coating material superimposing a mark disposed at a surface of a substrate according to an embodiment of the invention.

FIGS. 5a and 5b depict a top view and a cross-sectional view, respectively, of a coating material superimposing a mark at a substrate surface according to an embodiment of the invention.

### DETAILED DESCRIPTION OF THE INVENTION

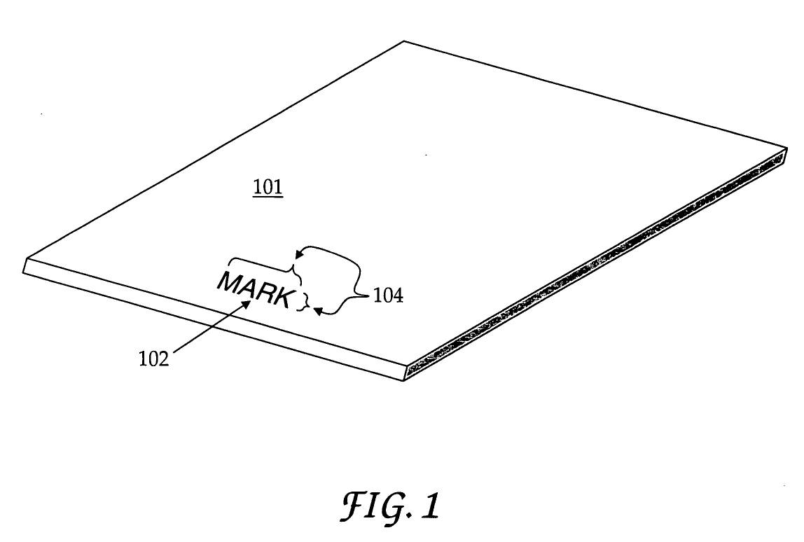

As depicted in FIG. 1, readable marks 102 on substrates 101 may be human readable (e.g., alphanumeric text) or machine readable (e.g., bar code), and the readable portion of a mark may comprise less then the entire mark or may comprise the entire mark. Reference hereinafter to a ‘readable mark’ or ‘mark’ means at least the readable portion of a mark. Both human and machine readable marks have a resolution (or ‘readability’) threshold below which readability decreases. The threshold will be different for different readers, be they human or machine, so there generally is no well defined threshold limit for readability. Readability will vary from person to person and or from machine to machine, depending on numerous variables. Further, for any particular reader, the threshold may be reasonably sharply defined, or it may constitute a range of progressively diminishing readability. Numerous factors can affect the readability of a mark, including the size and relative proximity of features comprising the mark, the color of the mark relative to a background material, the degree of transparency of materials overlying the mark, topography of the mark relative to a plane of a surface on, above or below which a mark is formed, and numerous other factors. In turn, these factors and characteristics of a mark, or any of numerous other factors affecting the readability of a mark, can change during a duration between the time a mark is first formed and the time(s) when a reader attempts to read a mark. Changes caused during normal manufacturing, testing, and use of a substrate can sometimes cause a mark to become unreadable to some readers. That is, the readability of a mark falls below a readability threshold relative to a particular reader or class of readers.

Mark resolution may fall below a readability threshold due to degradation of the materials from which and/or into which the mark is formed. However, degradation can be attenuated or prevented by disposing a protective polymer coating material so that it covers (superimposes) the mark and a portion of the substrate surface, as described according to embodiments presented herein. Particularly useful is a coating material that is durable against the environmental, chemical, or other conditions present during manufacturing, reliability testing and use of a substrate, that can degrade the readability of an otherwise unprotected mark.

One variable affecting the readability of a mark is the relative contrast of the mark to the background or surrounding materials. Contrast can be provided in a mark through numerous methods, at least one of which is by forming a mark with three-dimensional characteristics relative to a plane of a substrate at which the mark is formed. For example, a portion of a mark, perhaps a border or some text, can be impressed (imprinted) into a surface of a substrate, so that at least a portion of the mark lies below a plane of the surface of the substrate. In imprinting a mark, a die, stamp, or some other device is typically used which contains ridges or other raised features corresponding with the desired mark, or some portion of a mark. The die is typically placed at a surface of a substrate with the raised features in contact with or proximate to the surface, and sufficient force is applied, either progressively or suddenly, causing the raised features to penetrate into the surface of the substrate to a depth below the plane of the surface. The depth depends on numerous factors, including the density and hardness of the substrate, the force applied, and the height of the raised features, among other factors.

Likewise, a mark can include at least one material added (printed) onto a surface of a substrate so that at least a portion of the mark extends above a plane of the surface of the substrate. Printing typically involves using a template (pattern), stencil, stamp, or other device possessing a pattern corresponding to the mark or some portion of the mark. A transferable material, for example ink, paint, or an adhesive to name just a few, can be disposed at a surface of a device. That surface of the device is then positioned proximate to the substrate surface so that the transferable material makes contact with the substrate surface and some or all of it transfers and adheres with the substrate surface. Alternately, the device may constitute a stencil having openings corresponding to all or some portion of the mark. The stencil is placed at and approximately coplanar with a surface of a substrate, and a transferable material is drawn across the exposed surface of the stencil so that the openings in the stencil substantially fill with an amount of the material, the thickness of which corresponds with the thickness of the stencil.

Other marks may be formed at or into a surface of a substrate using heat, herein referred to as thermoforming. Thermoforming, in alternate embodiments, includes melting, scorching, or ablating material at a surface of a substrate, using for example a heated implement or a laser to engrave or otherwise define a mark or a portion of a mark at the substrate surface, although the embodiments are not so limited. Marks can also be formed by inlaying a contrasting material into a material of a substrate, either by removing substrate surface material and filling in the removed portions with the contrasting material, or by separately disposing the substrate surface material and the contrasting material adjacently during formation of the substrate. Lithographically produced marks can be formed by disposing a material at a surface of a substrate, then subtractively etching either those portions of the material not corresponding to the mark, or by etching away those portions of the material corresponding to the mark. Therefore, a lithographically defined mark may include some portions of a material etched away as well as other portions allowed to remain after etching.

A mark can also be formed by laminating a material at a surface of a substrate, or laminating a material at a layer of a substrate beneath a surface of the substrate in such a way that the mark is visible at the surface of the substrate. A laminated mark can be adhesively bonded, electrostatically bonded, chemically bonded, or thermally bonded with the substrate layer or surface, although the embodiments of bonding a laminated mark are not limited to those specifically listed here. Further, although numerous embodiments described above include a mark provided at a surface of a substrate, a mark can likewise be provided at a layer within a substrate, that is, somewhere between opposing exterior surfaces of a substrate, while still being visible at a surface of the substrate. Likewise, a mark can comprise separate portions or features of the mark disposed at different layers within and/or at the surface of a transparent substrate, so that the different portions or features at the surface and/or different layers of the substrate, when viewed from a proper viewing angle, constitute a mark. Some substrates are not typically considered ‘multilayer’ substrates. For example, a substrate can be formed of a single sheet of polymer resin wherein a mark is disposed within the polymer resin, interposed between opposing exterior surfaces of the sheet, prior to solidification of the polymer. For the purposes of embodiments of the invention described herein, anytime a mark is disposed within a substrate other than at an external surface, as in the example provided, the mark is considered to be disposed at a layer within the substrate.

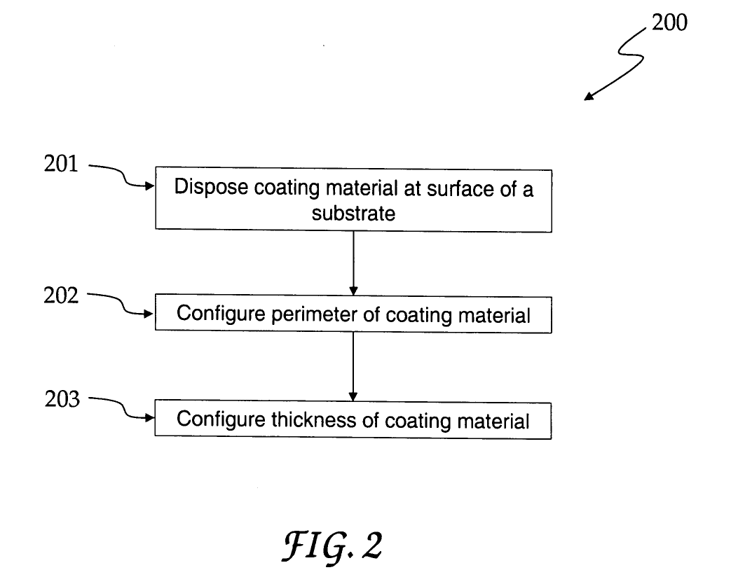

Therefore, marks provided and/or visible at a surface of a substrate, formed according to a wide variety of methods, can remain readable following manufacturing, reliability testing, and/or use by providing a protective coating material corresponding to and superimposing a mark. An embodiment of a method 200 depicted in FIG. 2, includes at 201 disposing a coating material at a surface of a substrate. In general, this will constitute disposing the coating material on a surface plane of a substrate. However, in some situations, particularly where a mark is formed within or visible through a portion of a substrate surface wherein a plane of the portion differs from a general plane of the substrate surface, the coating material can be disposed at the plane of that portion rather than a the general substrate surface plane. As shown by this example, even when an exterior surface of a substrate includes a plurality of planes, such instances can still be considered disposing the coating material at a surface of a substrate. Likewise, if another material is interposed between a substrate surface plane and a coating material, the coating material may still be said to be disposed at a surface of the substrate.

Commonly, the substrate upon which a mark is formed is a semiconductor substrate. Semiconductor substrates include substrates used to form IC packages such as BGA (ball grid array) packages, PGA (pin grid array) packages, LGA (land grid array) packages, packages utilizing lead frame interconnects (for external electrical connectivity), and others having an exterior surface suitable for receiving a readable mark, whether presently in use, in development, or not yet under development. Such packages typically include an IC device and a printed circuit substrate with which the IC device is coupled, either physically, electrically, or both. Examples of printed circuit substrates include boards (PCBs), cards, ribbons (flex substrate), or substrates specially designed for use in an IC package, commonly referred to as ‘package substrates’. A package also frequently has a ‘lid’, or ‘cover’ which may form a hermetic or non-hermetic seal with a substrate, enclosing one or more IC devices within a cavity. According to alternate embodiments, any of the IC device, the printed circuit substrate, or the lid/cover, or some combination of all or fewer then all of these items, can be a substrate(s) upon which a readable mark and a coating material are disposed. Other forms and materials that may be semiconductor substrates according to alternative embodiments include multilayer printed circuit substrates, semiconductor wafers, ceramic substrates, polymer substrates, flexible substrates, metallic substrates, and composite substrates, particularly when coupled with, comprising, or otherwise functionally or structurally associated with a semiconductor (e.g., IC) device. For example, a flexible printed circuit substrate (‘flex substrate’) configured to carry signals to and/or from a packaged IC device to another component of an electronic system, may have a readable mark formed thereon, the mark superimposed by a transparent coating material. In this example, the flex substrate is both structurally associated with an IC device (e.g., through a physical connection, although perhaps indirectly through an IC socketing device) and functionally associated by conveying an electrical signal from/to the IC device. A substrate need not be both structurally and functionally associated with an IC device to be a semiconductor substrate in all embodiments. It may be only structurally associated, or only functionally associated, or may be a semiconductor by virtue of its material characteristics and electrical properties.

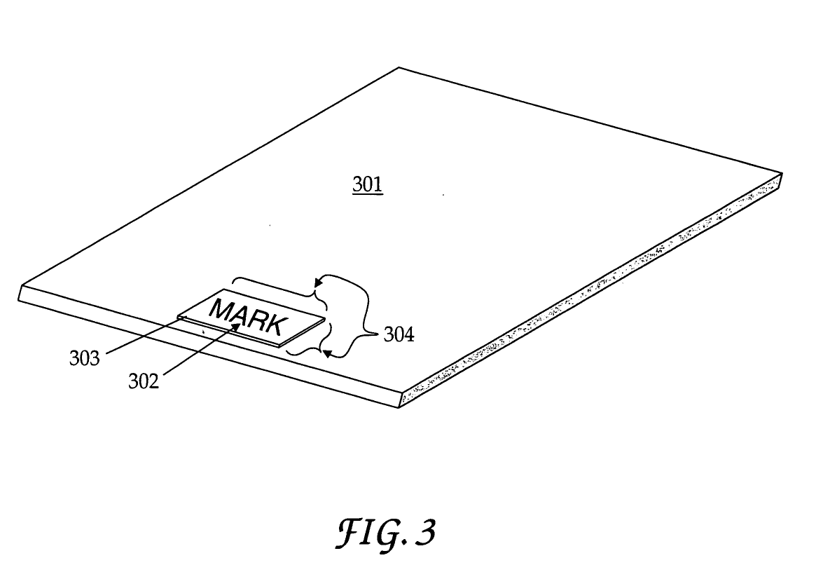

In general, as in the embodiment depicted in FIG. 3, a disposed coating material 303 will superimpose all or some portion of a mark 302, whether or not the mark is disposed at a plane of an exterior surface of a substrate 301 or is disposed at least partially at a layer of a substrate 301 other than an exterior surface. Further, in general, a disposed coating material 303 will have a perimeter 304 defined by an outer extent or lateral spread of the coating material 303 relative to a substrate 301 surface. Outside the perimeter 304 of the coating material 303, the portion(s) of an exterior surface of the substrate 301 not covered with coating material 303 may be exposed to the ambient environment. Alternatively, another material (e.g. a polyimide solder mask) may also be disposed to at least partially cover portions of the substrate 301 not covered by the coating material. Conversely, within the perimeter 304 of the coating material 303, the portion(s) of the exterior surface of the substrate 301 covered by the coating material 303 is/are not directly exposed to the ambient environment.

A mark 302 typically will also have a perimeter 104 (as in FIG. 1) marking the outer extent of the mark 302 in an X-Y axis relative to a plane of an external surface of a substrate 301, and a perimeter 304 of the coating material corresponds with the perimeter 104 of the mark 302. Occasionally, the extent of the perimeter 304 of the coating material 303 is at least coextensive with the perimeter 104 of the mark 302 with which it corresponds. Alternatively, the perimeters 104/304 of the mark 302 and the coating material 303 are coextensive in at least one direction or in one axis. In other occasions, the perimeter 304 of the coating material 303 extends somewhat beyond the perimeter 103 of the mark 302 in at least one direction or axis. Regardless whether the perimeter 304 of a coating material 303 is coextensive with the perimeter 104 of a mark 302, or extends to a greater or lesser extent in a particular direction or axis relative to the perimeter 104 of the mark 302, the perimeter 304 of the disposed coating material 303 typically corresponds approximately with the perimeter 104 of the mark 302. In this regard, the coating material 304 is unlike a polyimide or other solder mask material, for example, which is typically disposed across substantially an entire surface of a substrate (e.g. printed circuit board), excepting pads for electrical connection and other such isolated structures. In situations where a mark includes both readable portions and non-readable portions, disposing a coating material so that it superimposes only the readable portion(s) of the mark is sufficient in at least one aspect of the invention. In such situations, a perimeter of the coating material may be said to correspond with a perimeter of the readable portions of the mark.

A coating material 303 is a substantially transparent polymer material. For the purposes of this specification, a substantially transparent polymer is one which permits a reader to discern a mark 302 with sufficient resolution to correctly read a readable portion of a mark 302 when viewing the mark 302 through a thickness of the polymer material. Further, transparency is not limited to coating materials that are transparent to visible light (i.e., wavelength range of approximately 400-740 nanometers) only. A reader may employ a radiation source other than light within the visible spectrum for reading a mark. For example, radiation within the infrared or ultraviolet spectra, or other portions of the electromagnetic spectrum, may be used. Therefore, a transparent coating material will allow relatively unimpeded passage of energy at the utilized spectral range for reading a mark. Likewise, a laser light source having a relatively narrow bandwidth within the visible light spectrum may be used. In this situation, a coating material may be transparent to a bandwidth within or encompassing the bandwidth of the laser light, without being transparent to the entire visible light spectrum.

A mark may be relatively invisible to at least a class of readers until exposed to energy at a specific wavelength or bandwidth, when it then becomes visible to that class or readers. Likewise, a mark exposed to energy at first wavelength or bandwidth may emit energy at a second wavelength or bandwidth. The first wavelength or bandwidth may be either visible or invisible to the reader, however, the second, emitted wavelength or bandwidth is visible to at least a reader or a class of readers. A coating material, in this situation, is transparent to at least the first and second wavelengths/bandwidths. By these examples, embodiments of the invention are useful in preserving the readability of marks in, for example, information security, product authenticity, and stolen product recovery applications, where a mark or some portion of a mark may be visible only under specialized conditions.

A coating material, in addition to being transparent, also is relatively durable against a range of environmental, chemical, and mechanical conditions that could affect the readability of a mark throughout manufacturing, testing, and actual use. For example, a substrate bearing a readable mark can be exposed to a broad range of temperatures, humidity, chemicals in liquid and gaseous states, atmospheric pressures, relatively mild abrasives, handling mechanisms, shock and vibration, and other conditions or events that can degrade either the mark, the substrate, or both. While extremes of nearly any of these conditions can potentially reduce the readability of a mark, a coating material is generally capable of preserving the readability of a mark against a range of conditions typically encountered during ‘normal’ manufacturing, testing, and use conditions. Normal use conditions include those against which manufacturers of computer system and components for computer systems typically warrant their products during the duration of their standard warranty periods. These typically exclude abuse, misuse, and excessive exposure to liquids, dirt, and other contaminants, however a coating material according to embodiments of the invention described herein can typically also protect a mark against degradation due to many of these conditions as well. Test conditions defined by various industry and regulatory standards for component testing (e.g., U/L certification, FCC, CE), are also considered ‘normal’ test conditions, as are conditions used in tests normally conducted to ensure reliability and performance of products under extreme use conditions, (e.g., U.S. Military guidelines, N.A.S.A. guidelines).

Additionally, individual manufacturers and/or product reviewers occasionally prescribe testing in addition to and exceeding the requirements of the various industry standards, to ensure the quality and reliability of their products to their and/or their customers' satisfaction. Occasionally, this means testing products to the point of failure of the electronic and/or mechanical components. Included in reliability test ‘suites’, products are frequently exposed not only to extremes of temperature, humidity, and other conditions, but are also exposed to cycling between the extremes, designed to simulate use conditions. For example, products may be exposed to an elevated temperature of 165° C. for 350 hours. An example of an accelerated stress test can include exposure of products to 130° C. with 85% humidity for 100 hours. An example of thermal cycling can include exposing products to an environment which alternates between a low temperature of −55° C. and a high temperature of up to 125° C., for 750 such cycles. Each of these examples can be considered ‘normal’ test conditions simulating stress inducing use conditions. Normal manufacturing conditions also include exposure to elevated temperatures, exposure to chemicals in both liquid and gaseous forms, handling by numerous human and mechanical devices, and other conditions that can reduce the readability of a mark.

A coating material will preserve the readability of a mark against most if not all normal manufacturing, testing, and normal use conditions. A particularly durable material, polydimethylsiloxane (PDMS) having the chemical formula (CH₃)₃SiO[SiO(CH₃)₂]ₙSi(CH₃)₃, where n is the number of repeating monomer [SiO(CH₃)₂] units, and also sometimes referred to as dimethicone, provides such readability protection in at least one aspect of the invention. PDMS is transparent, has good wettability for many substrate materials, is generally considered to be relatively chemically inert, has good conformity with surfaces, provides high thermal stability (up to approximately 300° C.) with a CTE (coefficient of thermal expansion) of approximately 300 ppm/° C., and a low modulus of approximately 300 MPa. PDMS also lends itself readily to a convenient method for disposing a coating material; using a stencil to define a coating material placement, perimeter and thickness. This method is described in more detail below. Other types of siloxane-based polymers can also be utilized for this invention. For example, vinyl-terminated siloxane could be used instead of PDMS due to the similarities in the general properties between these polymers, as can other polymers having substantially similar characteristics. Therefore, the embodiments should not be construed as limited to those materials specifically listed herein, but rather is inclusive of others having characteristics similar to those possessed by PDMS and identified as being beneficial.

Disposing a coating material adjacent to a substrate includes, in one aspect, securely positioning a stencil adjacent to a surface of the substrate so that an opening formed through the stencil corresponds with a mark, and a perimeter of the opening corresponds with the intended placement of the perimeter of the coating material (once disposed) with respect to the mark. Similarly, where a plurality of marks are present, either a plurality of corresponding openings can be provided in the stencil, or a plurality of stencils each having one or more openings can be used. A thickness of a stencil adjacent to the opening corresponds closely with an intended final thickness of the coating material relative to the substrate surface. Depending on the shrinkage properties of the coating material used, the stencil can be thicker than the intended final thickness of the cured coating material by an amount approximately equal to the extent that the coating material tends to shrink when cured. The coating material, in the form of a relatively low viscosity resin, is then dispensed at the surface of the substrate within or closely adjacent to the perimeter of the opening in the stencil. A sufficient amount of coating material is disposed to substantially fill the opening. A substantially filled opening is one in which a coating material extends to or nearly to the perimeter of the opening in all or nearly all lateral dimensions with respect to the substrate surface, and extends from a plane of the substrate surface to a plane of the upper surface of the stencil relative to the substrate surface across all or nearly all of the area within the perimeter of the opening.

The coating material having been dispensed, it is then caused to move into and/or throughout the opening, substantially filling the opening as described above. Doing so configures a perimeter of the coating material, as shown in FIG. 2 at 202, to closely match the perimeter of the stencil opening(s). The coating material may be caused to move into the opening by drawing a leveling device across the surface of the stencil, pushing a flow front of coating material before the leveling device while leaving little or no coating material at the stencil surface in the areas across which the leveling device has already moved. By this action, the leveling device transits along a plane defined by the surface of the stencil. As the leveling device passes over the stencil, and while held against the stencil surface with sufficient force to prevent the leveling device from losing contact with the stencil surface, the leveling device causes the coating material in the stencil opening to assume a relatively planar upper surface (relative to the substrate surface) that is also substantially coplanar with the stencil surface traversed by the leveling device. Thus, when the leveling device completely transits the opening in the stencil surface, the opening is substantially filled with the coating material, and as set forth in FIG. 2 at 203, a thickness of the coating material is configured. Therefore, according to an embodiment so described, a thickness of a coating material corresponds closely to that of a stencil, and a coating material thickness can be alternatively configured either thicker or thinner by using a correspondingly thicker or thinner stencil. Likewise, a thickness of the coating material is conformal with (e.g., corresponds closely with) a surface of the substrate.

Alternatively, structures or features formed at a surface of a substrate can define at least a portion of a perimeter of the disposed coating material. For example, a portion of a material disposed at a substrate surface can be etched, ablated, peeled, grinded, dissolved, or otherwise partially or entirely removed to form a depression with a perimeter around a mark, or around a portion of a substrate surface where a mark is to be disposed. Likewise, a depth is established in the area where the material is removed relative to the surrounding portions where the material is not removed. A coating material can then be dispensed into the depression and within the perimeter in a quantity sufficient to substantially fill the area within the perimeter. In this way, the form and extent of the perimeter of the depression substantially defines the perimeter of the coating material. Likewise, a flowable coating material will flow throughout the depression, and once cured, may have a thickness configured to be substantially conformal with the substrate surface.

Following deposition, a coating material can be cured to harden it and ‘fix’ (durably establish) such dimensional characteristics as its thickness, perimeter, and configuration. Thermal curing entails exposing the coating material to an elevated temperature for a sustained duration of time. For instance, a coating material may be exposed to a temperature in a range of 150-175° C. for between 30-120 minutes, although the embodiments are not so limited. Depending on the coating material used, a different curing temperature or temperature range, or a longer or shorter duration may be selected. Further, the thermal source for curing a coating material can be provided by an oven, a hot plate, a heated air flow, or other sources or methods capable of exposing the coating material to a temperature or temperature range for a sufficient duration of time.

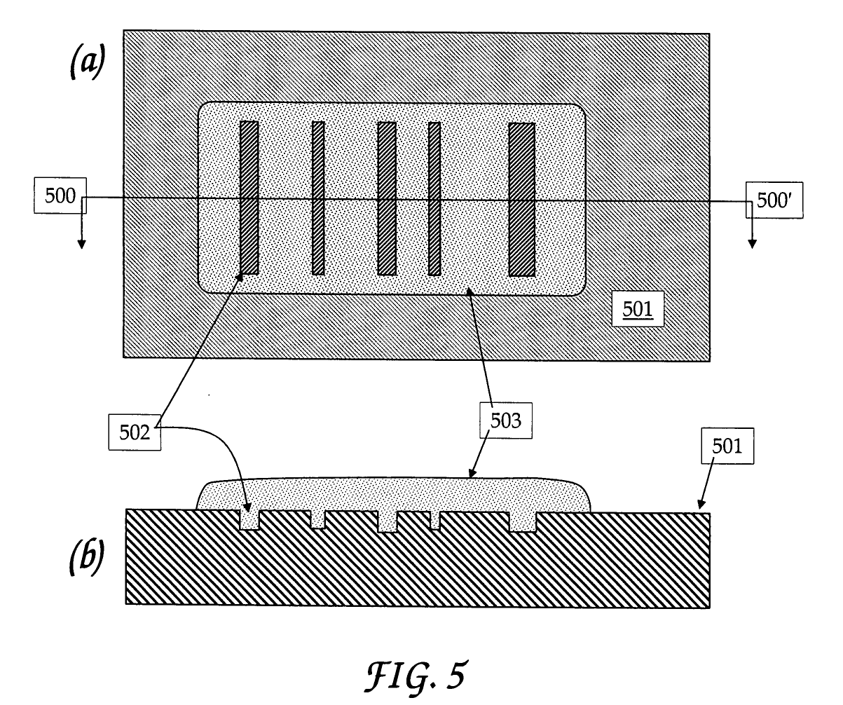

As mentioned, a beneficial characteristic of a material such as PDMS (and functionally similar materials) is that it is highly conformal with surfaces. As shown in FIGS. 5a and 5b (FIG. 5b is a cross-sectional view of the embodiment of FIG. 5a, taken through the line 500-500′), when disposed in a flowable form at a surface of a substrate 501, and superimposing a mark that possesses three dimensional contour, the coating material 503 conforms with the contours of the mark, filling recessed portions 502 and covering relatively elevated portions. Therefore, when cured, the coating material 503 forms a protective barrier between the mark and numerous environmental, mechanical, or other factors that can otherwise reduce the readability of the mark by damaging or degrading the mark. Further, the cured coating material itself is sufficiently durable that it is not easily damaged or degraded to an extent that would interfere with the readability of a mark superimposed by the coating material. Therefore, a mark protected by a coating material as described remains readable throughout manufacturing, reliability testing, and normal use.

A coating material could be applied within the normal manufacturing process flow for a semiconductor package. In one example, substrates arrive at the front end of a manufacturing line in thermoform trays from a supplier. Marks, such as a substrate lot identification (SLI) and serial number (SN) are formed onto each of the substrates. The substrates then proceed to an operation at which a polymer coating material is disposed at each substrate surface, superimposing the marks formed at the previous operation. Following this operation, the substrate sequentially proceeds through fluxing, paste printing, device placement, device attach, and solder paste reflow operations. At each operation, the SLI and/or SN may be read and entered into a data base to provide manufacturing data tracking and retention, as well as to enable production flow management. Curing of the coating material may take place at the reflow oven, or it may take place in a separate operation. Following manufacturing of an IC package, the packages or some representative sampling thereof are typically subjected to reliability testing. Throughout this testing, as well as the manufacturing process itself, the coating material protects the mark, preventing degradation that could otherwise detrimentally affect readability of the mark.

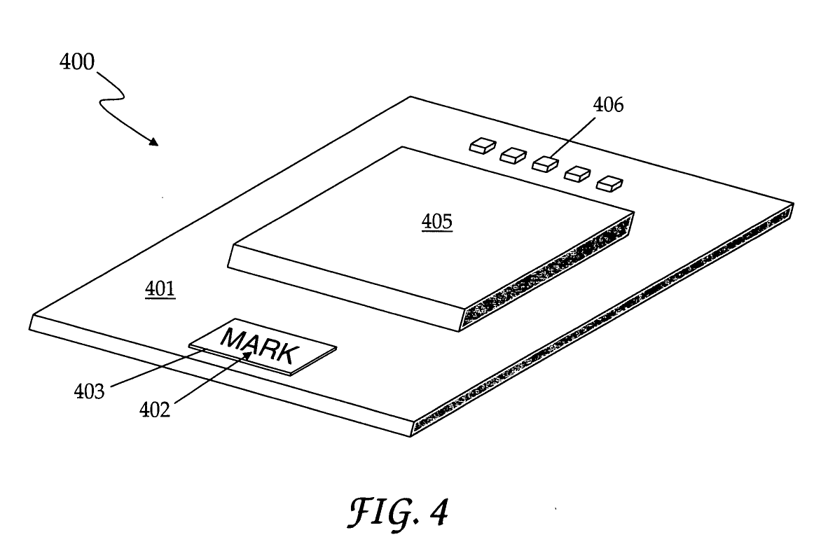

FIG. 4 depicts an embodiment of an assembly 400 including a semiconductor substrate 401 (e.g., an IC package substrate) with a readable mark 402 disposed at a surface of the substrate 401. Superimposing the mark 402 is a polymeric coating material 403 having characteristics as described above, for example polydimethylsiloxane (PDMS). A perimeter of the coating material 403 corresponds approximately with a perimeter of the mark 402, and a thickness of the coating material 403 is relatively conformal with the surface of the substrate 401. The coating material 403 is transparent, which allows the mark 402 to be read through the coating material 403. For example, the coating material 403 may be transparent to energy within the visible light spectrum, to energy in the ultraviolet spectral range(s), and/or to energy within the infrared spectral range, although the embodiments are not limited to transparency in the spectral ranges of these examples alone. Therefore, the mark 402 is capable of being read by a reader following reliability testing.

In embodiments such as that in FIG. 4, an integrated circuit (IC) device 405 is also electrically and/or physically coupled with the substrate 401. Examples of an IC device include a microprocessor, chipset device, and memory devices, although the embodiments are not so limited. Also coupled with the substrate may be other devices 406, for example capacitors, resistors, thermocouples, or other devices, electrical or otherwise, that are provided in or on portions of an IC package assembly 400. As described above, numerous forms of IC packages 405 are included in alternative embodiments. Taken generally, devices 405, 406 can include any devices designed to process, convert, regulate, detect, condition, store, receive, convey, or measure electrical signals, impulses, waves, or charges, and/or information so conveyed. Although embodiments described herein refer to a mark 402 being disposed at a surface of a substrate 401, a mark 402 may alternatively be formed at a surface of an IC device 405 or another device 406, the mark 402 being superimposed by a durable coating material 403, wherein the IC device 405 or other device 406 can also be considered a substrate for the mark 402.

An IC package assembly 400 can further comprise a portion of an electronic system, such as a computer system (e.g., mobile, desktop, server), an audio or video entertainment system (e.g., television, video media player, audio media player, satellite or cable signal converter), a system for monitoring or conducting environmental measurements (e.g., atmospheric, hydrologic, seismic, chemical), an industrial manufacturing system (e.g., robotic, analytical), a vehicular monitoring, navigation and/or control system (e.g., navigation, acceleration and deceleration control, emission monitoring and/or control, safety), or other systems that designed to operate via, or rely at least in part on processing, converting, regulating, conditioning, storing, receiving, conveying, detecting, or measuring electrical, optical, or wireless signals, images, impulses, waves, or charges, and/or information so conveyed. For example, an IC package assembly may be coupled with a computer motherboard, which is in turn assembled within a chassis of a computer system. The IC device is typically electrically coupled through the motherboard to peripheral devices, such as a monitor, input/output devices (e.g., keyboard, mouse, camera), as well as to other IC devices configured for similar and/or different purposes. In other computer systems, numerous peripheral devices may be integrated into the computer system chassis, such as the keyboard and monitor of a notebook computer, rather than being discrete but electrically connectable devices.

As a portion of a system as described, an IC package with a readable mark formed thereon provides benefits throughout the useful life of the system. For example, if a factory recall is initiated due to defective materials or assembly of an IC package, a readable mark identifying the substrate lot number of a substrate included in an IC package will enable a consumer to recognize if their system is affected by the recall. In another instance, a shipment of IC devices may be stolen, and later recovered. Readable marks on a portion of the IC devices may enable law enforcement authorities to determine if later recovered IC packages were included among the stolen shipment, perhaps enabling identification and apprehension of criminal parties involved in the theft. Therefore, by these and numerous other examples, the value of preserving the readability of a mark formed at a surface of a semiconductor substrate should be apparent.

Additionally, numerous benefits are derived by configuring a perimeter of a coating material to correspond approximately with a perimeter of a mark. First, substrates frequently have other, less durable coating materials disposed at their surfaces, such as solder mask materials. These materials are frequently infused with dyes of a particular color as may be preferred by a customer or for a particular application. By configuring a perimeter of the coating material to correspond with that of a mark, interference with other substrate coating materials can be avoided or minimized. Second, configuring a perimeter of a coating material to correspond approximately with a perimeter of a mark restricts the area covered by the coating material, enabling greater control of coating material thickness conformity. This is important because non-conformal coating materials can induce optical effects, which in turn can impair the readability of a mark. Where a coating material is disposed relatively thickly, configuring a perimeter of the coating material to correspond with that of a mark helps to prevent the coating material from interfering with placement and attachment of devices at a substrate surface, particularly when a thickness of the coating material is greater than a thickness of a soldermask material also disposed at the substrate surface. Further, an entire surface of a substrate in a package assembly may be entirely enclosed by a cover, leaving only a ‘window’ in the cover for viewing a mark. During handling, electrostatic discharges into or from the package substrate can find a conduction path through such a ‘window’ by contact or proximity to conductive materials introduced near or through the window, whether accidentally or intentionally introduced. A coating material superimposing the mark, with a perimeter corresponding approximately with the mark, and having a thickness greater than that of a solder mask layer, provides an enhanced dielectric barrier to prevent electrostatic damage to an IC device.

A mark according to the embodiments may be formed at the same surface of a substrate or at a different surface of the substrate, relative to an IC device coupled with the substrate. Likewise, a substrate may have one mark or a plurality of marks disposed upon it, and when a plurality of marks are present, they may be all dispose at one surface, or they may be disposed at more than one surface of the substrate. Where a plurality of marks are formed at a surface or a plurality of surfaces, they may all be superimposed by one type of coating material, or one subset of the marks may be superimposed by one type of coating material while another subset of the marks is/are superimposed by another type of coating material. Referring to devices 405 and 406 collectively, a substrate may have only one device coupled with a surface, or may have a plurality of devices coupled with a surface. Alternatively, a substrate may have one or more devices coupled with one surface, and also have one or more devices coupled with another surface. An IC package assembly also has, in embodiments, a cover coupled with at least one of the substrate and/or an IC device, and the cover may be either hermetically or non-hermetically sealed with either the substrate or the IC device accordingly. A coating material may partially overlap a soldermask material also disposed at a substrate surface, or alternatively, an area at a surface of a substrate corresponding to a perimeter of the coating material may be kept clear of soldermask so that there is little or no overlap between a coating material and a soldermask material. In some circumstances, a substrate will have a plurality of marks disposed at or visible at the substrate surface, and only a subset of those marks will be superimposed by a disposed coating material as described herein.

An IC package according to the embodiments described herein may be configured to be retained to or within a socket, or inserted into a slot, or coupled with a substrate by a reflowed electrically conductive member (e.g., metallic solder or conductive polymer member), or otherwise configured to provide an electrically conductive pathway for conveyance of electrical signals and/or power/ground pathways to and/or from the IC package. Alternatively, an IC package may be configured for receiving and/or conveying wireless signals, such as radio, optical, or other signals capable of being conveyed through the atmosphere, or via conductive pathways other than electrically conductive pathways (e.g., optical fiber).

In the above description, numerous specific details are set forth such as examples of specific materials or components in order to provide a thorough understanding of embodiments of the present invention. It will be apparent, however, to one skilled in the art that these specific details need not be employed to practice embodiments of the present invention. In other instances, well known components or methods have not been described in detail in order to avoid unnecessarily obscuring embodiments of the present invention.

The terms “on,” “above,” “below,” “between,” and “adjacent” as used herein refer to a relative position of, for example, one layer or element with respect to other layers or elements. As such, a first element disposed on, above or below another element may be directly in contact with the first element or may have one or more intervening elements. Moreover, one element disposed next to or adjacent to another element may be directly in contact with the first element or may have one or more intervening elements.

Any reference in the specification to “one embodiment” or “an embodiment” means that a particular feature, structure, or characteristic described in connection with the embodiment is included in at least one embodiment of the claimed subject matter. The appearances of the phrase, “in one embodiment” in various places in the specification are not necessarily all referring to the same embodiment. References herein to an ‘aspect’, ‘alternative’, ‘option’, or a similar term may also represent a separate embodiment including at least one unique feature, structure, or characteristic.

The foregoing detailed description and accompanying drawings are only illustrative and not restrictive. They have been provided primarily for a clear and comprehensive understanding of the embodiments of the invention, and no unnecessary limitations are to be understood therefrom. Numerous additions, deletions, and modifications to the embodiments described herein, as well as alternative arrangements, may be devised by those skilled in the art without departing from the spirit of the embodiments and the scope of the appended claims.

We claim:

1. A method, comprising:
disposing a siloxane-based polymer coating material at a surface of a semiconductor substrate, the surface having a readable mark formed thereupon and the coating material superimposing the mark;
configuring a perimeter of the coating material to correspond approximately with a perimeter of the mark; and
configuring a thickness of the coating material to be relatively conformal with the surface of the substrate, the mark remaining readable through the coating material.

2. The method of claim 1, wherein the mark is human readable.

3. The method of claim 1, wherein the substrate is selected from one of the group consisting of a multilayer printed circuit substrate, a semiconductor wafer, a ceramic substrate, a polymer substrate, a flexible substrate, a metallic substrate, and a composite substrate.

4. The method of claim 1, wherein the mark is at least one of a thermoformed mark, an impressed mark, a printed mark, a laminated mark, a lithographically produced mark, or an inlayed mark.

5. The method of claim 1, wherein the coating material fills and preserves a three dimensional contour of the mark relative to the substrate surface.

6. The method of claim 1, wherein the coating material is transparent to visible light.

7. The method of claim 1, further comprising curing the coating material.

8. The method of claim 7, wherein curing comprises heating the coating material for at least a first duration of time.

9. The method of claim 1, wherein the mark is capable of remaining readable through the coating material following reliability testing.

10. The method of claim 1, further comprising performing reliability testing on the marked substrate including the coating material, the mark remaining readable following testing.

11. An apparatus, comprising:
a semiconductor substrate bearing a readable mark; and
a siloxane-based polymer coating material disposed at a surface of the semiconductor substrate and superimposing the mark, a perimeter of the coating material corresponding approximately with a perimeter of the mark, a thickness of the coating material being relatively conformal with the substrate surface, and the coating material filling a preserving a three dimensional profile of the mark relative to the substrate surface throughout reliability testing.

12. The apparatus of claim 11, wherein the mark is human readable.

13. The apparatus of claim 11, wherein the substrate is selected from one of the group consisting of a multilayer printed circuit substrate, a semiconductor wafer, a ceramic substrate, a polymer substrate, a flexible substrate, a metallic substrate, and a composite substrate.

14. The apparatus of claim 11, wherein the mark is at least one of a thermoformed mark, an impressed mark, a printed mark, or an inlayed mark.

15. The apparatus of claim 11, wherein the coating material is transparent to visible light.

16. The apparatus of claim 11, wherein the mark is formed at an outer surface of the substrate.

17. An assembly, comprising:
a semiconductor substrate;
an integrated circuit device electrically coupled with the substrate;
a readable mark disposed at a surface of the substrate; and
a siloxane-based polymer coating material disposed at the surface of the substrate, the coating material superimposing the mark and having a perimeter corresponding approximately with a perimeter of the mark, and a thickness of the coating material being relatively conformal with the substrate surface.

18. The assembly of claim 17, wherein the coating material remains transparent, and the mark remains readable following reliability testing.

19. The assembly of claim 17, further comprising a second device at least one of electrically, or physically, or electrically and physically coupled with the substrate.

20. The assembly of claim 17, comprising one of a BGA package assembly, a PGA package assembly, an LGA package assembly, or a package assembly including a lead frame for external electrical connectivity.

21. The assembly of claim 17, wherein the assembly comprises a portion of a computer system.
